(19) United States
(12) Patent Application Publication
(10) Pub. No.: US 2009/0057779 A1
(43) Pub. Date: Mar. 5, 2009

(54) Semiconductor Device and Method of Fabricating the Same

(76) Inventor: Duck Ki JANG, Bucheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/197,989

(22) Filed: Aug. 25, 2008

(30) Foreign Application Priority Data
Aug. 27, 2007 (KR) 10-2007-0085990

(51) Int. Cl. H01L 21/8234; H01L 27/088

(52) U.S. Cl. 257/392; 438/275; 257/E27.06; 257/E21.618

(57) ABSTRACT

A semiconductor device and a method of fabricating the same are disclosed. The semiconductor device includes a semiconductor substrate having a first area implanted with first conductive type impurities; an isolating film defining a first active area and a second active area in the first area; first LDD areas spaced from each other on the first active area at a first interval and implanted with second conductive type impurities; and second LDD areas spaced from each other on the second active area at a second interval narrower than the first interval and implanted with the second conductive type impurities.

The present application claims priority under 35 U.S.C. 119 to Korean Patent Application No. 10-2007-0085990 (filed on Aug. 27, 2007), which is hereby incorporated by reference in its entirety.

### BACKGROUND

1. Field of the Invention

The invention relates to a semiconductor device and a method of fabricating the same.

2. Description of the Related Art

With the recent development of information processing techniques, there has been an increase in demand for a semiconductor device capable of operating with a high-voltage signal.

There has also been a demand for a semiconductor chip in which a transistor operable at high voltage, a transistor operable at intermediate voltage, and a transistor operable at low voltage are integrated.

### SUMMARY

Embodiments of the invention provide a semiconductor device in which a transistor operable at a predetermined voltage and a transistor operable at voltage lower than the predetermined voltage are formed on a single well or each of two wells having the same concentration of impurities, and a method of fabricating the same.

In one embodiment, the semiconductor device comprises a semiconductor substrate including a first area having first conductive type impurities therein; an isolating film defining a first active area and a second active area in the first area; first LDD areas spaced from each other on the first active area at a first interval and comprising second conductive type impurities therein; and second LDD areas spaced from each other on the second active area at a second interval narrower than the first interval and comprising the second conductive type impurities.

Another embodiment provides a semiconductor device comprising: a semiconductor substrate including a first well having first conductive type impurities therein and a second well having second conductive type impurities therein; a first transistor on the first well; and a second transistor on the second well. The first transistor includes a first gate electrode on the first well, and first LDD areas comprising second conductive type impurities in the first well. The second transistor includes a second gate electrode on the second well, second LDD areas comprising the second conductive type impurities in the second well, and halo areas under the second LDD areas comprising the second conductive type impurities having a concentration corresponding to the concentration of the second conductive type impurities in the first LDD areas.

Yet another embodiment provides a method of fabricating a semiconductor device, comprising the steps of: providing a semiconductor substrate having a first area including first conductive type impurities and a second area including second conductive type impurities; forming a first gate electrode on the first area and a second gate electrode on the second area; forming second LDD areas on lateral sides of the second gate electrode; and simultaneously forming first LDD areas on lateral sides of the first gate electrode and halo areas in lower portions of the second LDD areas.

In the semiconductor device according to various embodiments, the interval between the second LDD areas is narrower than that between the first LDD areas. Therefore, a transistor in the second active area has a shorter channel length than a transistor in the first active area, and is operable at relatively low voltage.

Even when the transistors are formed in a single well, or each of the transistors is formed in wells having the same impurity at the same concentration, the transistor formed in the second active area is operable at relatively low voltage.

### BRIEF DESCRIPTION OF THE DRAWINGS

FIG. 1 is a cross-sectional view of a semiconductor device according to an embodiment.

FIGS. 2a to 2f are cross-sectional views showing processes according to an exemplary method of fabricating a semiconductor device.

### DETAILED DESCRIPTION OF THE EMBODIMENTS

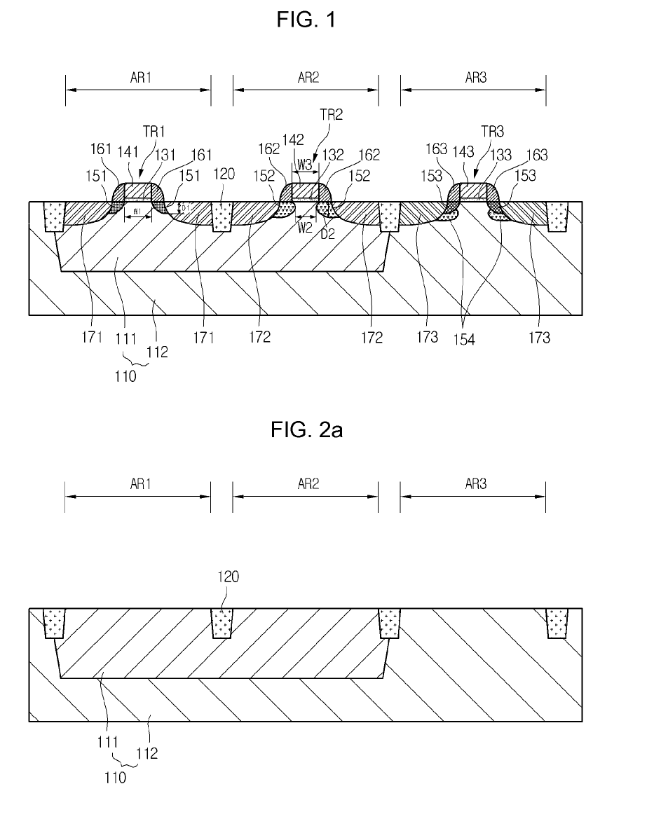

FIG. 1 is a cross-sectional view of a semiconductor device according to an embodiment of the present invention.

Referring to FIG. 1, a semiconductor device includes a semiconductor substrate 110, an isolating film 120, a first transistor TR1, a second transistor TR2, and a third transistor TR3.

The first substrate 110 includes a first area 111 including, for example, P-type impurities and a second area 112 including, for example, N-type impurities. For example, the first area 111 may be a p-well including P-type impurities.

The concentration of the P-type impurities in the first area 111 is lower than that of the N-type impurities in the second area 112. The P-type impurities may comprise boron (B), by way of example, and the N-type impurities may comprise phosphorus (P) and/or arsenic (As) by way of example.

The isolating film 120 is formed in the semiconductor substrate 110. The isolating film 120 in the first area 111 defines a first active area AR1 and a second active area AR2. The isolating film 120 in the second area 112 may define a third active area AR3. By way of example, the isolating film 120 may comprise an oxide and be formed through a STI (swallow trench isolation) process or a LOCOS (local oxidation) process.

The first transistor TR1 is in the first active area AR1. The first transistor TR1 includes a first gate insulating film 131, a first gate electrode 141, first LDD areas 151, first gate spacers 161, and first source/drain areas 171.

The first gate insulating film 131 is on the first semiconductor substrate 110. The first gate insulating film 131 may comprise silicon oxide (SiOx) by way of example. The first gate insulating film 131 may insulate the first gate electrode 141 from the channel in the substrate 110 therebelow.

The first gate electrode 141 is on the first gate insulating film 131. The first gate electrode 141 may comprise polycrystalline silicon (which may be doped with an n-type or p-type impurity, as described herein), aluminum (Al), copper (Cu), molybdenum (Mo), tungsten (W), titanium (Ti), or a combination thereof (e.g., an AlCu or TiW alloy; Mo, W or Ti silicide; etc.), by way of example.

The first gate spacers 161 are on lateral sides of the first gate electrode 141. The first gate spacers 161 may comprise an oxide (e.g., silicon dioxide) and/or a nitride (e.g., silicon nitride), by way of example. The first gate spacers 161 insulate the lateral sides of the first gate electrode 141 and/or provide a mask (in addition to the gate 141) for the ion implantation process to form source/drain terminals 171.

The first LDD areas 151 are below the first gate spacers 161 and are formed by ion implantation with an N-type impurity. Each of the first LDD areas 151 is spaced at a first interval W1 and has a first depth D1. The concentration of the N-type impurity in the first LDD areas 151 is a first (predetermined) concentration.

The first source/drain areas 171 are on lateral sides of the first gate spacers 161 and are formed by ion implantation with a high concentration of an N-type impurity. The first source/drain areas 171 are adjacent to the first LDD areas 151.

The second transistor TR2 is in the second active area AR2. The second transistor TR2 includes a second gate insulating film 132, a second gate electrode 142, second LDD areas 152, second gate spacers 162, and second source/drain areas 172.

The second gate insulating film 132 is on the semiconductor substrate 110. The second gate insulating film 132 may comprise the same material and/or have the same thickness as (or smaller thickness than) the first gate insulating film 131. If the second gate insulating film 132 has a smaller thickness than the first gate insulating film 131, it is generally about 50-80% of the thickness of the first gate insulating film 131.

The second gate electrode 142 is on the second gate insulating film 132. The second gate electrode 142 may comprise the same material and have the same thickness as the first gate electrode 141.

The second gate spacers 162 are on the lateral sides of the second gate electrode 142. The second gate spacers 162 may comprise the same materials and have the same thickness(es) as the first gate spacers 161. The second gate spacers 162 may function as a mask (in addition to the gate 142) for the ion implantation process to form source/drain terminals 172.

The second LDD areas 152 are below the second gate spacers 162 and are formed by ion implantation with an N-type impurity. Each of the second LDD areas 152 is spaced at a second interval W2 and has a second depth D2.

The second LDD areas 152 protrude in a direction of the channel, opposite to the source/drain terminals 172. Therefore, the second interval W2 is narrower than the first interval W1 by the length of the protrusion or extension, and may be narrower than the interval W3 of the second gate electrode 142 by the protrusion length, depending on the extent of any diffusion of the implanted N-type impurity.

The second depth D2 is greater than the first depth D1, and a second concentration of the N-type impurity in the second LDD areas 152 is higher than the concentration of the N-type impurity in the first LDD areas 151. The N-type impurity in the first LDD areas 151 need not be the same as the N-type impurity in the second LDD areas 152.

The second source/drain areas 172 are on the lateral sides of the first gate spacers 161 and are formed by ion implantation with a high concentration of an N-type impurity. The second source/drain areas 172 are adjacent to the second LDD areas 152.

The first and second intervals W1 and W2 are the respective lengths of the channels of the first transistor M1 and second transistor M2, wherein the length of the channel of the second transistor TR2 is shorter than that of the first transistor TR1. The second transistor TR2 is thereby operable at a lower operating voltage than the first transistor TR1. For example, the first transistor TR1 may operate at voltage of about 20V to 30V, and the second transistor TR2 may operate at voltage of about 4V to 5V. In other words, a voltage of about 20V to 30V may be applied to the first source/drain areas 171, by way of example, and a voltage of about 4V to 6V may be applied to the second source/drain areas 172, by way of example.

The third transistor TR3 is on the third active area AR3. The third transistor TR3 includes a third gate insulating film 133, a third gate electrode 143, third LDD areas 153, third gate spacers 163, and third source/drain areas 173.

The third gate insulating film 133 is on the semiconductor substrate 110. The third gate insulating film 132 may comprise the same material as and may have a thickness the same as or different from the first gate insulating film 131 and/or the second gate insulating film 132.

The third gate electrode 143 is on the third gate insulating film 133. The third gate electrode 143 may comprise the same material and/or the same thickness as the first gate electrode 141 and/or the second gate electrode 142.

The third gate spacers 163 are on the lateral sides of the third gate electrode 143. The third gate spacers 163 may comprise the same material in the same thickness(es) as the first gate spacers 161 and/or the second gate spacers 162. The third gate spacers 163 insulate the lateral sides of the third gate electrode 143 and/or may function as a mask (in addition to the gate 143) for the ion implantation process to form source/drain terminals 173.

The third LDD areas 153 are below the third gate spacers 163 and are formed by ion implantation with a low concentration of a P-type impurity. Each of the third LDD areas 153 is spaced at a third interval.

The halo areas 154 are formed below the third LDD areas 153 by ion implantation with an N-type impurity. The halo areas 154 reduce a punch through phenomenon during operation of the third transistor TR3.

The third source/drain areas 173 are on the lateral sides of the third gate spacers 163 and are formed by ion implantation with a high concentration of a P-type impurity. The third transistor TR3 includes impurity regions having higher concentration than the impurity regions in the first areas 111, so the third transistor TR3 may operate at a lower operating voltage than the first transistor TR1 and the second transistor TR2. By way of example, a voltage of about 1V to 1.5V may be applied to the third source/drain areas 173.

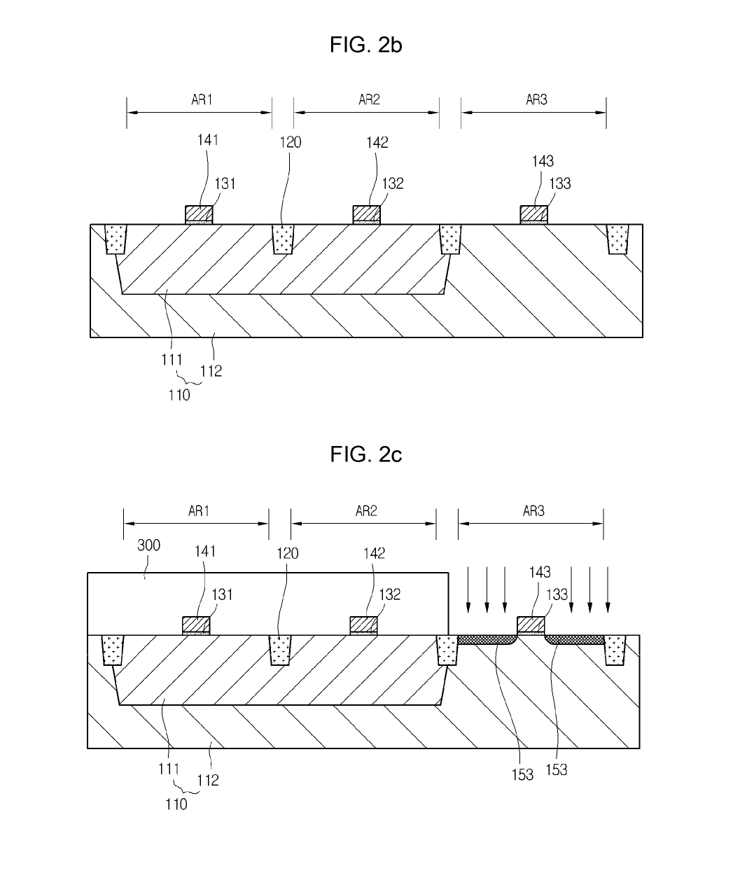

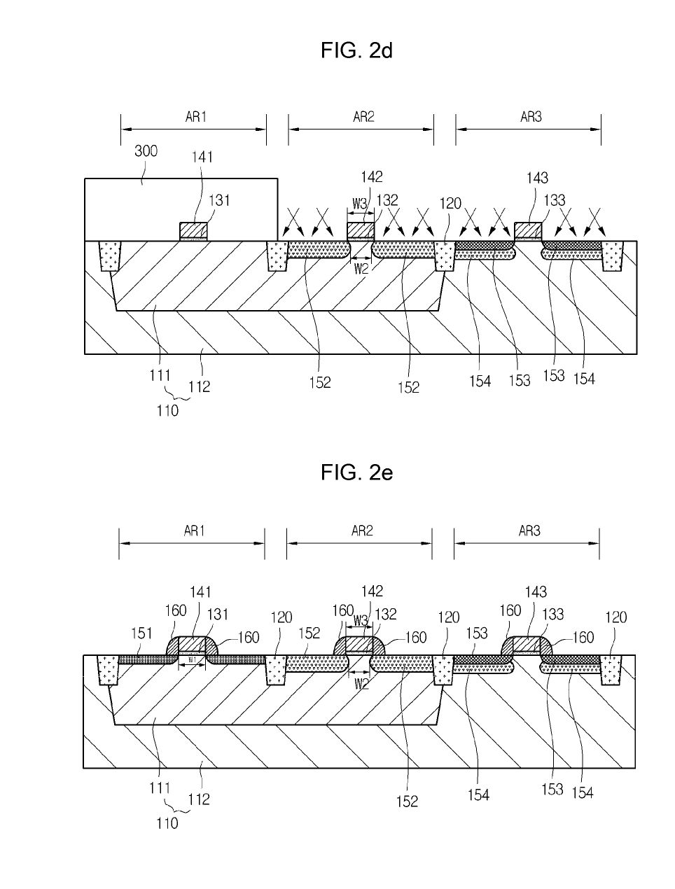

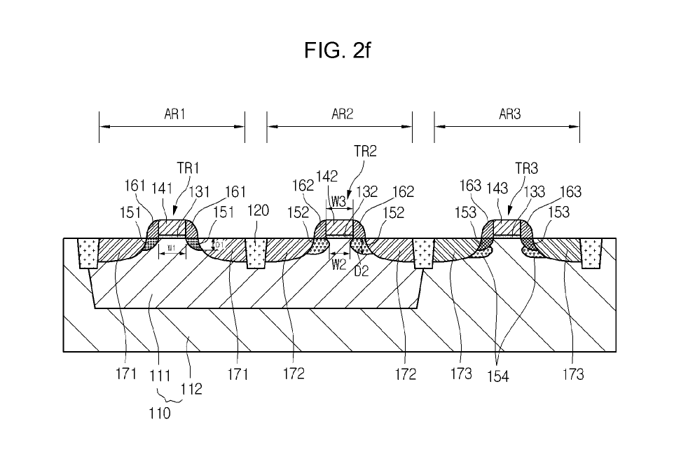

FIGS. 2a to 2f are cross-sectional views showing processes according to an exemplary method of fabricating a semiconductor device.

Referring to FIG. 2a, a predetermined portion of an N-type semiconductor substrate implanted with N-type impurities is implanted with P-type impurities to form a p-well. In other words, the semiconductor substrate 10 includes a first area 111 comprising P-type impurities and a second area 112 comprising N-type impurities.

A trench is formed in the semiconductor substrate 110 having the p-well 111 therein through a STI process, and the trench is filled with oxide, thereby forming an isolating film 120. Prior to depositing oxide to fill the trench, a thin liner oxide may be grown on the surface of the trench, and a thin liner nitride layer maybe deposited on the liner oxide layer. By means of the isolating film 120, a first active area AR1 and a second active area AR2 are defined in the first area 111, and a third active area AR3 is defined in the second area 112.

Referring to FIG. 2b, after the isolating film 120 is formed, an oxide film is formed on the semiconductor substrate 110 through an annealing process (e.g., conventional wet or dry oxidation of silicon), and a polysilicon layer is formed on the oxide film (generally by chemical vapor deposition from a precursor gas such as silane or disilane).

Thereafter, the oxide film and the poly silicon layer are patterned through a photolithographic masking and etching process, and first to third gates are formed on the semiconductor substrate 110, wherein first to third gate electrodes 141, 142, 143 are formed on the first to third gate insulating layers 131, 132, 133.

Referring to FIG. 2c, a first photoresist pattern 300 exposing the third active area AR3 is formed, and P-type impurities are implanted at a first concentration into the semiconductor substrate 110 on which the first to third gate electrodes 141, 142, 143 are formed, using the first photoresist pattern 300 and the third gate electrode 143 as masks.

Referring to FIG. 2d, after the P-type impurities are implanted into the third active area AR3 to form third LDD areas 153, the first photoresist patter 300 is removed through an ashing process, and a second photoresist pattern 400 covering the first active area AR1 is formed. Thereafter, N-type impurities are implanted at a second concentration into both the second active area AR2 and the third active area AR3 through a tilted ion implantation process, using the second photoresist pattern 400 and second and third gate electrodes 142, 143 as masks. As a result, second LDD areas 152 are formed on lateral sides of the second gate electrode 142, and halo areas 154 are formed below the third LDD areas 153. The second LDD areas 152 and the halo areas 154 have the same depth and concentration of N-type impurities. At this time, the depth of the second LDD areas 152 and halo areas 154 is greater than that of the third LDD areas 153.

Also, the second LDD areas 152 each protrude in opposite directions (e.g., towards the channel). This is because they are formed through the tilted ion implantation process. The protruded portions of the second LDD areas 152 are formed on the lower portions of the second gate 142. The interval between the second LDD areas 152 is thereby shorter than that of the second gate electrode 142. Also, the halo areas 154 may also protrude or extend by an amount the same as or similar to that of the second LDD areas 152, and the channel length below gate 143/142 may be the same as or similar to that of the second gate electrode 142.

Referring to FIG. 2e, N-type impurities are implanted at a third concentration into the first active area AR1 using the first gate electrode 141 as a mask, and first LDD areas 151 are formed. Although the second and third active areas may be masked with a photoresist pattern (similar to pattern 300 in FIG. 2c), because the third concentration of the n-type impurities is lower than the first concentration and the second concentration, the unmasked implantation of n-type impurities to form first LDD areas 151 does not significantly affect the properties and/or characteristics of second LDD areas 152 and third LDD areas 153.

Thereafter, a nitride film (and, optionally, an oxide film above and/or below the nitride film) is/are formed on the semiconductor substrate 110 having the first LDD areas 151 therein, and the nitride film (and optional oxide film[s]) is/are etched using an anisotropic etching process such as an etchback process. As a result, first to third gate spacers 161, 162, 163 are formed on the lateral sides of the first to third gate electrodes 141, 142, 143.

Referring to FIG. 2f, after masking the third active area AR3 with a patterned photoresist as described herein (not shown), a high concentration of N-type impurities are implanted into the first active area AR1 and the second active area AR2 using the first gate electrode 141, the second gate electrode 142, the first gate spacer 161, and the second gate spacers 162 as masks. As a result, first source/drain areas 171 and second source/drain areas 172 are formed.

Thereafter, the mask over the third active area AR3 is removed (e.g., by ashing) and a patterned photoresist is formed over active areas AR1 and AR2 (not shown, but as described herein for photoresist pattern 300 in FIG. 2c). A (high) concentration of P-type impurities are implanted into the third active area AR3 using the third gate electrode 143 and the third gate spacers 163 as masks, thereby forming third source/drain areas 173.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a semiconductor substrate including a first area having first conductive type impurities therein;
an isolating film defining a first active area and a second active area in the first area;
first LDD areas spaced from each other in the first active area at a first interval, comprising second conductive type impurities; and
second LDD areas spaced from each other in the second active area at a second interval narrower than the first interval, comprising the second conductive type impurities.

2. The semiconductor device according to claim 1, wherein the second LDD areas have a concentration of the second conductive type impurities that is higher than that of the first LDD areas.

3. The semiconductor device according to claim 1, wherein the semiconductor substrate includes a second area implanted with the second conductive type impurities; third LDD areas spaced from each other in the second active area at a third interval, comprising the first conductive type impurities; and halo areas in lower portions of the third LDD areas, comprising the second conductive type impurities.

4. The semiconductor device according to claim 3, wherein the first area has a concentration of the first conductive type impurities that is lower than a concentration of the second conductive type impurities in the second area.

5. The semiconductor device according to claim 3, wherein a concentration of the second conductive type impurities in the second LDD areas corresponds to that of the second conductive type impurities in the halo areas.

6. The semiconductor device according to claim 1, wherein the second LDD areas have a greater depth than the first LDD areas.

7. The semiconductor device according to claim 1, further comprising:
a gate electrode on the second active area and having a greater width than the second interval.

8. A semiconductor device, comprising:
a semiconductor substrate including a first well comprising first conductive type impurities and a second well comprising second conductive type impurities;
a first transistor on the first well; and
a second transistor on the second well,
wherein the first transistor includes a first gate electrode on the first well and first LDD areas comprising second conductive type impurities in the first well, and the second transistor includes a second gate electrode formed the second well, second LDD areas comprising second conductive type impurities in the second well, and halo areas under the second LDD area, comprising the second conductive type impurities in a concentration corresponding to a concentration of the second conductive type impurities in the first LDD areas.

9. The semiconductor device according to claim 8, wherein the first transistor has a higher driving voltage than that of the second transistor.

10. The semiconductor device according to claim 9, further comprising:
a third transistor on the first well and having a higher driving voltage than that of the first transistor.

11. A method of fabricating a semiconductor device, comprising the steps of:
providing a semiconductor substrate having a first area including first conductive type impurities and a second area including second conductive type impurities;
forming a first gate electrode on the first area and a second gate electrode on the second area;
forming second LDD areas on lateral sides of the second gate electrode; and
simultaneously forming first LDD areas on lateral sides of the first gate electrode and halo areas in lower portions of the second LDD areas.

12. The method according to claim 11, wherein forming the second LDD areas comprises implanting the first conductive type impurities into the semiconductor substrate using the second gate electrode as a mask.

13. The method according to claim 11, wherein simultaneously forming the first LDD areas and the halo areas comprises implanting the second conductive type impurities into the semiconductor substrate by a tilted ion implantation process using the first gate electrode and the second gate electrode as masks.

14. The method according to claim 13, wherein simultaneously forming the first LDD areas and the halo areas comprises implanting the second conductive type impurities at an angle of about 20° to 40°.
